(19) United States
(12) Patent Application Publication
(10) Pub. No.: US 2020/0041851 A1
(43) Pub. Date: Feb. 6, 2020

(54) ARRAY SUBSTRATE, DISPLAY PANEL AND DISPLAY DEVICE

(71) Applicants: BOE TECHNOLOGY GROUP CO., LTD.; CHONGQING BOE OPTOELECTRONICS TECHNOLOGY CO., LTD.

(72) Inventors: Zhijian QI, Beijing (CN); Ni YANG, Beijing (CN); Keke GU, Beijing (CN); Yi DAN, Beijing (CN)

(21) Appl. No.: 15/735,486

(22) PCT Filed: May 18, 2017
(86) PCT No.: PCT/CN2017/084939

§ 371 Date: Dec. 11, 2017

(30) Foreign Application Priority Data
Sep. 9, 2016 (CN) 201610815278.3

(51) Int. Cl. G02F 1/1343; G02F 1/1335; G02F 1/1362; G02F 1/1368; H01L 27/12

(52) U.S. Cl. CPC G02F 1/134309; G02F 1/133514; H01L 27/124; G02F 1/1368; G02F 1/136286

(57) ABSTRACT

Disclosure are an array substrate, a display panel and a display device. The array substrate includes a base substrate and a plurality of pixel units disposed on the base substrate. Each of the pixel units includes a first subpixel unit and a second subpixel unit; the first subpixel unit includes a first pixel electrode and a first common electrode; the second subpixel unit includes a second pixel electrode and a second common electrode which are insulated from each other; the first pixel electrode is electrically connected with the second pixel electrode; and the stacking sequence of the first pixel electrodes and the first common electrodes in the direction perpendicular to the base substrate is opposite to the stacking sequence of the second pixel electrodes and the second common electrodes in the direction perpendicular to the base substrate. The array substrate can effectively improve poor quality such as afterimage.

### TECHNICAL FIELD

Embodiments of the present disclosure relate to an array substrate, a display panel and a display device.

### BACKGROUND

In the technical field of displays, thin-film transistor liquid crystal display (TFT-LCD) is widely applied in the fields such as TV, computer and mobile phone due to the advantages of light and thin design, high brightness, high integration, powerful functions, flexible processes, low cost, etc. With the continuous development of liquid crystal display (LCD) technology, people have higher requirement on the display quality of LCDs.

In a horizontal electric field display mode, taken as one type of display mode with wide viewing angle and high transmittance of TFT-LCDs, multi-dimensional electric fields are formed by electric fields produced at edges of slit electrodes in the same plane and electric fields produced between a slit electrode layer and a plate electrode layer, so that liquid crystal molecules in all the alignments between and over the slit electrodes in a liquid crystal cell can rotate, and hence the liquid crystal working efficiency and the light transmittance can be improved.

### SUMMARY

At least one embodiment of the present disclosure provides an array substrate, a display panel and a display device. The array substrate comprises a base substrate and a plurality of pixel units disposed on the base substrate. Each of the pixel units includes a first subpixel unit and a second subpixel unit; the first subpixel unit includes a first pixel electrode and a first common electrode which are insulated from each other; the second subpixel unit includes a second pixel electrode and a second common electrode which are insulated from each other; the first pixel electrode is electrically connected with the second pixel electrode; and the stacking sequence of the first pixel electrodes and the first common electrodes in the direction perpendicular to the base substrate is opposite to the stacking sequence of the second pixel electrodes and the second common electrodes in the direction perpendicular to the base substrate. The array substrate neutralizes or reduces the brightness distortion caused by DC bias by arrangement of two subpixel units, in which the positions of the pixel electrode and the common electrode are opposite, in the same pixel unit, and hence effectively improves the poor qualities such as afterimage caused by DC bias. Moreover, the array substrate can also neutralize or reduce the brightness variation caused by the coupling of data lines and the pixel electrodes or the common electrodes, and hence effectively improve the poor qualities such as crosstalk.

At least one embodiment of the present disclosure provides an array substrate, which comprising: a base substrate; and a plurality of pixel units disposed on the base substrate, each of the pixel units comprises a first subpixel unit and a second subpixel unit; the first subpixel unit comprises a first pixel electrode and a first common electrode which are insulated from each other, the second subpixel unit comprises a second pixel electrode and a second common electrode which are insulated from each other; the first pixel electrode is electrically connected with the second pixel electrode; and the stacking sequence of the first pixel electrode and the first common electrode in the direction perpendicular to the base substrate is opposite to the stacking sequence of the second pixel electrode and the second common electrode in the direction perpendicular to the base substrate.

For example, in the array substrate provided by an embodiment of the present disclosure, the first common electrode and the second pixel electrode are arranged in the same layer and have a slit; the first pixel electrode and the second common electrode are arranged in the same layer, and the first common electrode and the second pixel electrode are arranged on one side of the first pixel electrode and the second common electrode away from the base substrate.

For example, in the array substrate provided by an embodiment of the present disclosure, both the first pixel electrode and the second common electrode are transparent conductive plate electrodes.

For example, in the array substrate provided by an embodiment of the present disclosure, the array substrate further comprises: a plurality of gate lines; and a plurality of data lines, each of the gate lines is disposed between the first subpixel unit and the second subpixel unit; each of the data lines is perpendicular to each of the gate lines; and the first subpixel unit and the second subpixel unit belonging to a same one of the pixel units are respectively connected with a same one of the data lines.

For example, in the array substrate provided by an embodiment of the present disclosure, the array substrate further comprises: a thin-film transistor, comprising: a gate electrode, a source electrode and a drain electrode, the gate electrode is electrically connected with one of the gate lines; the source electrode is electrically connected with one of the data lines; and the drain electrode is respectively electrically connected with the first pixel electrode and the second pixel electrode.

For example, in the array substrate provided by an embodiment of the present disclosure, the array substrate further comprises: a first thin film transistor and a second thin film transistor, wherein the first thin film transistor comprises a first gate electrode, a first source electrode and a first drain electrode; the first gate electrode is electrically connected with one of the gate lines; the first source electrode is electrically connected with one of the data lines; the first drain electrode is connected with the first pixel electrode; the second thin film transistor comprises a second gate electrode, a second source electrode and a second drain electrode; the second gate electrode is electrically connected with one of the gate lines; the second source electrode is electrically connected with one of the data lines; and the second drain electrode is electrically connected with the second pixel electrode.

For example, in the array substrate provided by an embodiment of the present disclosure, an angle between an extension direction of the slit of the first common electrode and an extension direction of the gate line is greater than 0 degree and less than 90 degrees; and an angle between an extension direction of the slit of the second pixel electrode and an extension direction of the gate line is greater than 0 degree and less than 90 degrees.

For example, in the array substrate provided by an embodiment of the present disclosure, a slit of the first pixel electrode is axisymmetrical to the slit of the second pixel electrode after rotating for 180 degrees.

For example, in the array substrate provided by an embodiment of the present disclosure, the first pixel unit comprises a first domain and a second domain; the second pixel unit comprises a third domain and a fourth domain; the slit in the first domain and the slit in the second domain have different extension directions; and the slit in the third domain and the slit in the fourth domain have different extension directions.

For example, in the array substrate provided by an embodiment of the present disclosure, an angle between the extension direction of the slit in the first domain and the extension direction of the slit in the second domain is greater than 0 degree and less than 90 degrees.

At least one embodiment of the present disclosure provides a liquid crystal display panel, comprising; an array substrate; an opposed substrate arranged opposite to the array substrate; and a liquid crystal layer disposed between the array substrate and the opposed substrate, the array substrate is any one of the abovementioned array substrates.

For example, in the liquid crystal display panel provided by an embodiment of the present disclosure, the opposed substrate comprises color filters in one-to-one correspondence with the plurality of pixel units; and the first subpixel unit and the second subpixel unit correspond to a same one of the color filters.

At least one embodiment of the present disclosure provides a display device, comprising any one of the abovementioned liquid crystal display panel.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention, not limitative to the present disclosure.

FIG. 1 is a schematic plan view of an array substrate provided by an embodiment of the present disclosure;

FIG. 2 is a schematic structural view of a pixel unit in an embodiment of the present disclosure;

FIG. 3 is a schematic sectional view of a pixel unit in an embodiment of the present disclosure;

FIG. 4 is a schematic sectional view of another pixel unit in an embodiment of the present disclosure;

FIG. 5 is a schematic diagram of a pixel unit in an embodiment of the present disclosure;

FIG. 6 is a schematic diagram of another pixel unit in an embodiment of the present disclosure; and

FIG. 7 is a schematic structural view of an LCD panel provided by an embodiment of the present disclosure.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the disclosure. Based on the described embodiments herein, one person skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” and so on which are used in the description and the claims of the present application for invention, are not intended to indicate any sequence, amount or importance, but distinguish various components. The terms “includes”, “including”, “includes”, “including”, etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

The inventor(s) of the application notices in the study that: the adoption of the spot lights as the light source assembly will result in the problems such as uneven brightness; and the spot lights is unfavorable for realizing the narrow-bezel design of the transparent splicing device due to a relatively large size The inventor(s) of the application has noticed in the study that: in the LCD field, poor qualities such as afterimage, crosstalk and greenish phenomenon are factors which affect the display quality of LCDs. The inventor(s) of the application has thought of arranging two regions, in which the position relationship of a pixel electrode and a common electrode are reverse, in one pixel unit to neutralize and reduce the poor display qualities caused by DC bias, so as to effectively improve afterimage and other relevant poor qualities caused by DC bias.

Embodiments of the present disclosure provide an array substrate, a display panel and a display device. The array substrate comprises a base substrate and a plurality of pixel units disposed on the base substrate. Each of the pixel units includes a first subpixel unit and a second subpixel unit; the first subpixel unit includes a first pixel electrode and a first common electrode which are insulated from each other; the second subpixel unit includes a second pixel electrode and a second common electrode which are insulated from each other, the first pixel electrode is electrically connected with the second pixel electrode; and the stacking sequence of the first pixel electrode and the first common electrode in the direction perpendicular to the base substrate is opposite to the stacking sequence of the second pixel electrode and the second common electrode in the direction perpendicular to the base substrate. The array substrate neutralizes or reduces the brightness distortion caused by DC bias by arrangement of two subpixel units, in which the positions of the pixel electrode and the common electrode are opposite, in the same pixel unit, and hence effectively improves the poor qualities such as afterimage caused by DC bias. Moreover, the array substrate can also neutralize or reduce the brightness variation caused by the coupling of data lines and the pixel electrodes or the common electrodes, and hence effectively improve the poor qualities such as crosstalk.

Hereafter, the array substrate, the display panel and the display device provided by the embodiments of the present disclosure will be described with reference to the accompanying drawings.

### First Embodiment

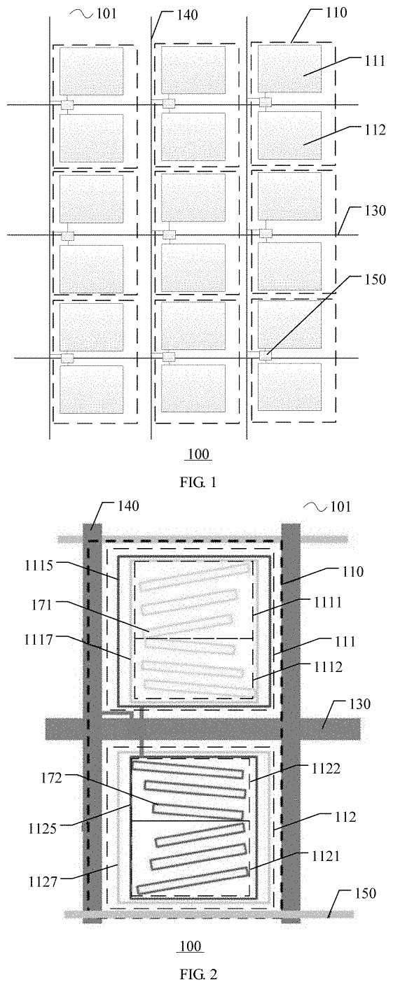

The embodiment provides an array substrate. As illustrated in FIGS. 1 and 2, the array substrate includes a base substrate 101 and a plurality of pixel units 110 disposed on the base substrate 101. Each of the pixel units 110 includes a first subpixel unit 111 and a second subpixel unit 112. The first subpixel unit 111 includes a first pixel electrode 1115 and a first common electrode 1117 which are insulated from each other; the second subpixel unit 112 includes a second pixel electrode 1125 and a second common electrode 1127 which are insulated from each other; and the first pixel electrode 1115 is electrically connected with the second pixel electrode 1125, for instance, the first pixel electrode 1115 and the second pixel electrode 1125 are connected with each other through a lead or an electrode and may be applied with the same data signal. The stacking sequence of the first pixel electrode 1115 and the first common electrode 1117 in the direction perpendicular to the base substrate 101 is opposite to the stacking sequence of the second pixel electrode 1125 and the second common electrode 1127 in the direction perpendicular to the base substrate 101. For instance, as shown in FIG. 2, the first pixel electrode 1115 is disposed below the first common electrode 1117, namely the first common electrode 1117 is disposed on one side close to the base substrate 101; and the second pixel electrode 1125 is disposed above the second common electrode 1127, namely the second common electrode 1127 is disposed on one side away from the base substrate 101. Of course, the embodiment of the present disclosure includes but not limited thereto. The first pixel electrode may also be disposed above the first common electrode and the second pixel electrode may also be disposed below the second common electrode.

In the array substrate provided by the embodiment, the pixel unit is divided into the first pixel unit and the second pixel unit; and the first pixel electrode in the first pixel unit is electrically connected with the second pixel electrode in the second pixel unit, that is to say, the first pixel unit and the second pixel unit are used for displaying the same pixel and the same gray scale and applied with the same data signal. When an LCD panel adopting the array substrate provided by the embodiment has the phenomenon of DC bias, namely when the LCD panel adopting the array substrate provided by the embodiment has DC voltage components, as ion impurities in the LCD panel will move along the DC electric field direction formed by the DC voltage and be gathered, the gathered ion impurities will form a reverse DC electric field opposite to the DC electric field direction formed by the DC voltage. At this point, as the stacking sequence of the first pixel electrode and the first common electrode in the direction perpendicular to the base substrate is opposite to the stacking sequence of the second pixel electrode and the second common electrode in the direction perpendicular to the base substrate, the brightness distortions on the first pixel unit and the second pixel unit caused by the reverse DC electric field are opposite and hence can be mutually neutralized or reduced; and the influence of DC bias on the first pixel unit and the second pixel unit, taken as one whole (pixel unit) for displaying the same pixel and the same gray scale and being applied with the same data signal, can be also reduced or eliminated, so that afterimage and other poor qualities caused by DC bias can be effectively improved. Therefore, the array substrate provided by the embodiment can neutralize or reduce the brightness distortion caused by DC bias by arrangement of two subpixel units, in which the positions of the pixel electrode and the common electrode are opposite, in the same pixel unit, and hence effectively improve the poor qualities such as afterimage caused by DC bias. It should be noted that the pixel unit refers to a pixel unit used for displaying the same pixel and the same gray scale and applied with the same data signal. For instance, when the LCD panel adopting the array substrate provided by the embodiment is an RGB LCD panel, the pixel unit may be a red pixel unit, a green pixel unit or a blue pixel unit.

For instance, in the array substrate provided by one example of the embodiment, as shown in FIG. 1, the plurality of pixel units 110 are arranged on the base substrate 101 in an array and used for displaying an image. The array substrate further includes a plurality of gate lines 130 and a plurality of data lines 140. Each of the gate lines 130 is disposed between the first subpixel unit 111 and the second subpixel unit 112; the data line 140 is perpendicular to the gate line 130; and the first subpixel unit 111 and the second subpixel unit 112 belonging to the same pixel unit 110 are respectively connected with the same data line 140.

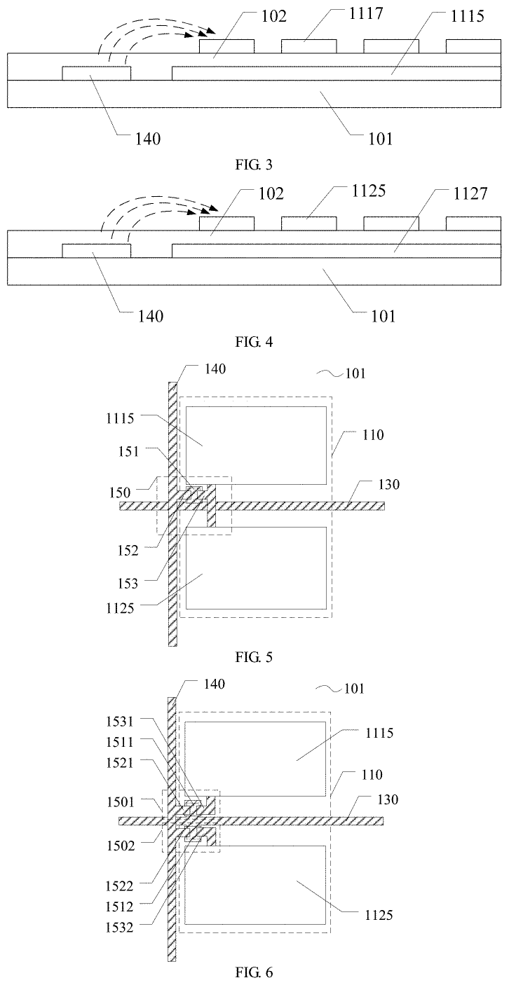

In the array substrate provided by the embodiment, the plurality of pixel units 110 are arranged on the base substrate 101 in an array, and time-division drive mode is usually adopted to drive the array substrate to display. Taking one pixel unit 110 in the plurality of pixel units 110 as an example, in a case where there is a scanning signal on the gate line 130 corresponding to the pixel unit 110, the data line 140 simultaneously applies a data signal to the first pixel electrode 1115 and the second pixel electrode 1125 in the pixel unit 110, and the pixel unit 1110 begins to display, in a case where the scanning signal on the gate line 130 corresponding to the pixel unit 110 disappears, the pixel unit 110 displays continuously through a storage capacitor, and at this point, there are data signals applied to other pixel units on the data line 140, the data line will be coupled with a surface electrode (an electrode between the pixel electrodes or the common electrodes away from the array substrate) in the pixel unit 110. As shown in FIG. 3, in the first pixel unit 111, the data line 140 may be coupled with the first common electrode 1117, so as to lower or raise the potential of the first common electrode 1117. As shown in FIG. 4, in the second pixel unit 112, the data line 140 may be coupled with the second pixel electrode 1125, so as to lower or raise the potential of the second pixel electrode 1125. That is to say, the data line 140 is simultaneously coupled with the first common electrode 1117 and the second pixel electrode 1125, and the coupling direction is same (simultaneously lowered or raised). Thus, the brightness variations of the first pixel unit 111 and the second pixel unit 112 caused by the coupling of the signal line 140 are just opposite and hence can be mutually compensated or neutralized, so that the phenomena such as crosstalk and greenish caused by the coupling capacitance can be effectively improved. It should be noted that: in a case where the first pixel electrode is disposed below the first common electrode and the second pixel electrode is also disposed above the second common electrode, the data line is simultaneously coupled with the first pixel electrode and the second common electrode. No limitation will be given here in the present disclosure.

For instance, in the array substrate provided by one example of the embodiment, as shown in FIG. 5, the array substrate further comprises a thin film transistor 150. The thin film transistor 150 includes a gate electrode 151, a source electrode 152 and a drain electrode 153; the gate electrode 151 is electrically connected with the gate line 130; the source electrode 152 is electrically connected with the data line 140; and the drain electrode 153 is respectively electrically connected with the first pixel electrode 1115 and the second pixel electrode 1125. Thus, the array substrate can simultaneously apply a data signal to the first pixel electrode and the second pixel electrode belonging to the same pixel unit through one thin film transistor.

For instance, in the array substrate provided by one example of the embodiment, as shown in FIG. 6, the array substrate comprises a first thin film transistor 1501 and a second thin film transistor 1502. The first thin film transistor 1501 includes a first gate electrode 1511, a first source electrode 1521 and a first drain electrode 1531. The second thin film transistor 1502 includes a second gate electrode 1512, a second source electrode 1522 and a second drain electrode 1532. The first gate electrode 1511 and the second gate electrode 1512 are electrically connected with the gate line 130; the first source electrode 1521 and the second source electrode 1522 are electrically connected with the data line 140; and the first drain electrode 1531 and the second drain electrode 1532 are respectively electrically connected with the first pixel electrode 1115 and the second pixel electrode 1125. Thus, the array substrate can respectively apply a data signal to the first pixel electrode and the second pixel electrode belonging to the same pixel unit through two thin film transistors.

### Second Embodiment

On the basis of the first embodiment, the embodiment provides an array substrate. As shown in FIG. 2, the first common electrode 1117 and the second pixel electrode 1125 are arranged in the same layer and have a slit; the first pixel electrode 1115 and the second common electrode 1127 are arranged in the same layer; and the first common electrode 1117 and the second pixel electrode 1125 are disposed above the first pixel electrode 1115 and the second common electrode 1127, namely disposed on one side of the first pixel electrode 1115 and the second common electrode 1127 away from the base substrate. Thus, horizontal electric fields can be formed between the first pixel electrodes and the first common electrodes and between the second pixel electrodes and the second common electrodes to drive liquid crystal molecules disposed on the array substrate. It should be noted that the first pixel electrode may also be disposed above the first common electrode and the second pixel electrode may also be disposed below the second common electrode, as long as the stacking sequence of the first pixel electrode and the first common electrode in the direction perpendicular to the base substrate is opposite to the stacking sequence of the second pixel electrode and the second common electrode in the direction perpendicular to the base substrate. At this point, the first pixel electrode and the second common electrode are arranged in the same layer and have a slit; the first common electrode and the second pixel electrode are arranged in the same layer; and the first pixel electrode and the second common electrode are disposed above the first common electrode and the second pixel electrode.

For instance, in the array substrate provided by one example of the embodiment, both the first pixel electrode and the second common electrode are transparent conductive plate electrodes. Thus, in the array substrate, multi-dimensional electric fields are formed by electric fields produced at edges of the first common electrodes or the second pixel electrodes with slits in the same plane and electric fields produced between the first common electrodes with the slits and the plate first pixel electrodes or between the second pixel electrodes with the slits and the plate second common electrodes, so that all the liquid crystal molecules over the first common electrodes and the second pixel electrodes of the array substrate provided by the embodiment can rotate, and hence the liquid crystal working efficiency and the light transmittance can be improved.

For instance, in the array substrate provided by one example of the embodiment, as shown in FIG. 2, an angle between the extension direction of a slit 171 of the first common electrode 1117 and the extension direction of the gate line 130 is greater than 0 degree and less than 90 degrees, and an angle between the extension direction of a slit 172 of the second pixel electrode 1125 and the extension direction of the gate line 130 is greater than 0 degree and less than 90 degrees Thus, the visible angle of the liquid crystal display panel adopting the array substrate provided by the embodiment can be increased by setting an angle of greater than 0 degree and less than 90 degrees between the extension direction of the slit of the surface electrode (an electrode among the pixel electrodes or the common electrodes away from the array substrate, namely the first common electrode or the second pixel electrode) and the extension direction of the gate line.

For instance, in the array substrate provided by one example of the embodiment, the slit 171 of the first common electrode 1117 is axisymmetrical to the slit 172 of the second pixel electrode 1125 after rotating for 180 degrees, and a symmetric axis may be the gate line 130 disposed between the first common electrode 1117 and the second pixel electrode 1125. Of course, the embodiment of the present disclosure includes but is not limited thereto. The symmetric axis may also be a center line of the first common electrode 1117 and the second pixel electrode 1125. Thus, the pixel unit 110 in the array substrate has two different domains, namely the first pixel unit and the second pixel unit. Therefore, the visible angle of the LCD panel adopting the array substrate provided by the embodiment can be further increased.

For instance, in the array substrate provided by one example of the embodiment, as shown in FIG. 2, the first pixel unit 111 includes a first domain 1111 and a second domain 1112; the second pixel unit 112 includes a third domain 1121 and a fourth domain 1122; the slits 171 in the first domain 1111 and the second domain 1112 have different extension directions; and the slits 172 in the third domain 1121 and the fourth domain 1122 have different extension directions. Thus, the pixel unit 110 in the array substrate has four different domains, namely the first domain, the second domain, the third domain and the fourth domain, so that the visible angle of the LCD panel adopting the array substrate provided by the embodiment can be further increased.

For instance, in the array substrate provided by one example of the embodiment, as shown in FIG. 2, an angle between the extension direction of the slit 171 in the first domain 1111 and the extension direction of the slit 172 in the second domain 1112 is greater than 0 degree and less than 90 degrees.

### Third Embodiment

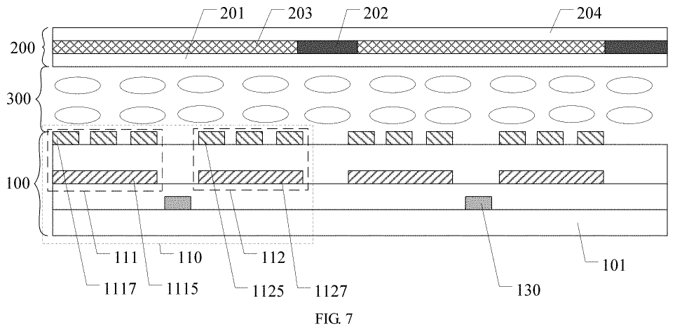

The embodiment provides a liquid crystal display panel. As illustrated in FIG. 7, the liquid crystal display panel comprises an array substrate 100, an opposed substrate 200, and a liquid crystal layer 300 disposed between the array substrate 100 and the opposed substrate 200. The array substrate 100 is any foregoing array substrate. Thus, in the liquid crystal display panel, as two subpixel units, in which the positions of the pixel electrode and the common electrode are opposite, are arranged in the same pixel unit, on one hand, the brightness distortion caused by DC bias can be neutralized or reduced, so as to effectively improve the poor qualities such as afterimage caused by DC bias, and on the other hand, the phenomena such as crosstalk and greenish caused by the coupling capacitance can be effectively improved. In addition, as the liquid crystal display panel comprises any foregoing array substrate, the liquid crystal display panel has the advantages corresponding to the advantages of the array substrate in the liquid crystal display panel, which may refer to relevant description in the above embodiment.

For instance, in the liquid crystal display panel provided by one example of the embodiment, the opposed substrate 200 includes color filters (CFs) 201 in one-to-one correspondence with the plurality of pixel units 110, and the first subpixel unit 111 and the second subpixel unit 112 correspond to the same color filter 201. For instance, the color filter 201 may be a red color filter, a blue color filter or a green color filter.

For instance, in the liquid crystal display panel provided by one example of the embodiment, the opposed substrate 200 further includes black matrix (BM) patterns 202 disposed between the color filters 201 and cover glass 204 disposed on one side of the opposed substrate 200 away from the liquid crystal layer 300.

### Fourth Embodiment

The embodiment provides a display device, which comprises any foregoing liquid crystal display panel. The display device may be: any product or component with display function such as a mobile phone, a tablet PC, a TV, a display, a notebook computer, a digital picture frame or a navigator. As the display device comprises any foregoing LCD panel, the display device has the advantages corresponding to the advantages of the LCD panel in the display device, and no further description will be given here in the embodiment. In addition, other structures or components in the display device may refer to the prior art, and no further description will be given here in the embodiment.

The following statements should be noted:

(1) The accompanying drawings involve only the structure(s) in connection with the embodiment(s) of the present disclosure, and other structure(s) can be referred to common design(s).

(2) For the purpose of clarity only, in accompanying drawings for illustrating the embodiment(s) of the present disclosure, the thickness and size of a layer or a structure may be enlarged. However, it should understood that, in the case in which a component or element such as a layer, film, area, substrate or the like is referred to be “on” or “under” another component or element, it may be directly on or under the another component or element or a component or element is interposed therebetween.

(3) In case of no conflict, features in one embodiment or in different embodiments can be combined.

The foregoing is only the preferred embodiments of the present invention and not intended to limit the scope of protection of the present invention. The scope of protection of the present invention should be defined by the appended claims.

The application claims priority to the Chinese patent application No. 201610815278.3, filed Sep. 9, 2016, the disclosure of which is incorporated herein by reference as part of the application.

1. An array substrate, comprising:
a base substrate; and
a plurality of pixel units disposed on the base substrate,
wherein each of the pixel units comprises a first subpixel unit and a second subpixel unit;
the first subpixel unit comprises a first pixel electrode and a first common electrode which are insulated from each other;
the second subpixel unit comprises a second pixel electrode and a second common electrode which are insulated from each other;
the first pixel electrode is electrically connected with the second pixel electrode; and the stacking sequence of the first pixel electrode and the first common electrode in the direction perpendicular to the base substrate is opposite to the stacking sequence of the second pixel electrode and the second common electrode in the direction perpendicular to the base substrate.

2. The array substrate according to claim 1, wherein the first common electrode and the second pixel electrode are arranged in the same layer and have a slit; the first pixel electrode and the second common electrode are arranged in the same layer; and the first common electrode and the second pixel electrode are arranged on one side of the first pixel electrode and the second common electrode away from the base substrate.

3. The array substrate according to claim 2, wherein both the first pixel electrode and the second common electrode are transparent conductive plate electrodes.

4. The array substrate according to claim 2, further comprising:
a plurality of gate lines; and
a plurality of data lines,
wherein each of the gate lines is disposed between the first subpixel unit and the second subpixel unit; each of the data lines is perpendicular to each of the gate lines; and the first subpixel unit and the second subpixel unit belonging to a same one of the pixel units are respectively connected with a same one of the data lines.

5. The array substrate according to claim 4, further comprising:
a thin-film transistor, comprising: a gate electrode, a source electrode and a drain electrode,
wherein the gate electrode is electrically connected with one of the gate lines; the source electrode is electrically connected with one of the data lines; and the drain electrode is respectively electrically connected with the first pixel electrode and the second pixel electrode.

6. The array substrate according to claim 4, further comprising:
a first thin film transistor and a second thin film transistor,
wherein the first thin film transistor comprises a first gate electrode, a first source electrode and a first drain electrode; the first gate electrode is electrically connected with one of the gate lines; the first source electrode is electrically connected with one of the data lines; the first drain electrode is connected with the first pixel electrode; the second thin film transistor comprises a second gate electrode, a second source electrode and a second drain electrode; the second gate electrode is electrically connected with one of the gate lines; the second source electrode is electrically connected with one of the data lines; and the second drain electrode is electrically connected with the second pixel electrode.

7. The array substrate according to claim 4, wherein an angle between an extension direction of the slit of the first common electrode and an extension direction of the gate line is greater than 0 degree and less than 90 degrees; and an angle between an extension direction of the slit of the second pixel electrode and an extension direction of the gate line is greater than 0 degree and less than 90 degrees.

8. The array substrate according to claim 7, wherein a slit of the first common electrode is axisymmetrical to the slit of the second pixel electrode after rotating for 180 degrees.

9. The array substrate according to claim 8, wherein the first pixel unit comprises a first domain and a second domain; the second pixel unit comprises a third domain and a fourth domain; the slit in the first domain and the slit in the second domain have different extension directions; and the slit in the third domain and the slit in the fourth domain have different extension directions.

10. The array substrate according to claim 9, wherein an angle between the extension direction of the slit in the first domain and the extension direction of the slit in the second domain is greater than 0 degree and less than 90 degrees.

11. A liquid crystal display panel, comprising:
an array substrate;
an opposed substrate arranged opposite to the array substrate; and
a liquid crystal layer disposed between the array substrate and the opposed substrate,
wherein the array substrate is the array substrate according to claim 1.

12. The display panel according to claim 11, wherein the opposed substrate comprises color filters in one-to-one correspondence with the plurality of pixel units; and the first subpixel unit and the second subpixel unit in each of the pixel units correspond to a same one of the color filters.

13. A display device, comprising the liquid crystal display panel according to claim 11.

14. The array substrate according to claim 3, further comprising:
a plurality of gate lines; and
a plurality of data lines,
wherein each of the gate lines is disposed between the first subpixel unit and the second subpixel unit; each of the data lines is perpendicular to each of the gate lines; and the first subpixel unit and the second subpixel unit belonging to a same one of the pixel units are respectively connected with a same one of the data lines.

15. The array substrate according to claim 14, further comprising:
a thin-film transistor, comprising: a gate electrode, a source electrode and a drain electrode,
wherein the gate electrode is electrically connected with one of the gate lines; the source electrode is electrically connected with one of the data lines; and the drain electrode is respectively electrically connected with the first pixel electrode and the second pixel electrode.

16. The array substrate according to claim 14, further comprising:
a first thin film transistor and a second thin film transistor,
wherein the first thin film transistor comprises a first gate electrode, a first source electrode and a first drain electrode; the first gate electrode is electrically connected with one of the gate lines; the first source electrode is electrically connected with one of the data lines; the first drain electrode is connected with the first pixel electrode; the second thin film transistor comprises a second gate electrode, a second source electrode and a second drain electrode; the second gate electrode is electrically connected with one of the gate lines; the second source electrode is electrically connected with one of the data lines; and the second drain electrode is electrically connected with the second pixel electrode.

17. The array substrate according to claim 14, wherein an angle between an extension direction of the slit of the first common electrode and an extension direction of the gate line is greater than 0 degree and less than 90 degrees; and an angle between an extension direction of the slit of the second pixel electrode and an extension direction of the gate line is greater than 0 degree and less than 90 degrees.
